(19) United States
(12) Patent Application Publication
(10) Pub. No.: US 2011/0290551 A1
(43) Pub. Date: Dec. 1, 2011

(54) Protective structure enclosing device on flexible substrate

(75) Inventor: Sang In LEE, Sunnyvale, CA (US)

(73) Assignee: SYNOS TECHNOLOGY, INC., Sunnyvale, CA (US)

(21) Appl. No.: 13/107,750

(22) Filed: May 13, 2011

Related U.S. Application Data
(60) Provisional application No. 61/348,216, filed on May 25, 2010.

(51) Int. Cl. H05K 5/00; H05H 1/24; C23C 16/40

(52) U.S. Cl. 174/520; 427/255.7; 427/535

(57) ABSTRACT

A structure for protecting a device includes a first layer, one or more first microstructures on the first layer, and a second layer disposed on the first layer. The second layer is disposed on a surface of the first layer on which one or more microstructures are provided. The microstructure may have a hemispheric shape or other random shapes having a curved surface. Since the area of the interface surface between layers is increased due to the at least one microstructure, the stress per unit area of the interface surface is reduced. Further, the microstructure increases the length of the path that ambient species need to travel in order to reach a device or other active components, thereby reducing the amount of infiltrating ambient species.

### CROSS-REFERENCE TO RELATED APPLICATION

This application claims priority under 35 U.S.C. §119(e) to co-pending U.S. Provisional Patent Application No. 61/348,216, filed on May 25, 2010, which is incorporated by reference herein in its entirety.

### BACKGROUND

1. Field of Art

The present invention relates to a structure for protecting a device, more particularly to a structure having microstructures between layers to disperse stress and prevent ingress of ambient species.

2. Description of the Related Art

Flexible substrates are employed in various electronic devices such as organic light emitting diode (OLED) devices or other display devices. FIG. 1 is a cross-sectional diagram illustrating a conventional structure including a flexible substrate. The structure includes a flexible substrate 100 on which a device 125 is disposed. An organic layer 120 is disposed on the device 125 and the substrate 100. Further, an inorganic layer 115 is disposed on the organic layer 120 followed by an organic layer 110. The multiple layers 110, 115, 120 of organic and inorganic layers may be disposed to prevent ambient species from coming into contact with the device 125 or other active components. By preventing contact, a structure that has good operating characteristics and long shelf life can be fabricated. The ambient species may include oxidizers (e.g., oxygen or carbon dioxide) and reducers (e.g., hydrogen or carbon monoxide).

Despite the presence of the multiple layers 110, 115, 120, the ambient species may still infiltrate and come into contact with the device 125 or other active components. Taking the example of FIG. 1, the routes that the ambient species may come into contact with the device 125 include: (i) an interface surface between the organic layer 120 and the substrate 100, (ii) interface surfaces between the organic/inorganic layers 110, 115, 120, (iii) infiltration through the organic layers 120, 110, (iv) infiltration through the inorganic layer 115, and (v) infiltration through the substrate 100.

Another issue often encountered in the flexible substrates is cracking. As the substrate 100 is bent, stress in the substrate 100 is increased. The increased stress may lead to cracks in the layers 110, 115, 120 disposed on the flexible substrate 100, which shortens the lifespan or degrades the performance of device 125 or other active components disposed on the flexible substrate 100.

### SUMMARY

Embodiments provide a structure for enclosing a device and a method for forming the structure. The structure includes a first layer, one or more microstructures formed on the first layer, and a second layer formed on the first layer and the one or more microstructures. The second layer and the one or more microstructures are of different materials. Each of the microstructures has a first curved surface protruding from the first layer.

### BRIEF DESCRIPTION OF DRAWINGS

FIG. 1 is a cross-sectional diagram illustrating a conventional structure including a flexible substrate.

FIG. 2 is a cross-sectional diagram illustrating a structure for protecting a device according to an embodiment.

FIG. 3A is a cross-sectional diagram illustrating a structure for enclosing a device, according to one embodiment.

FIG. 3B is a flowchart illustrating a method of manufacturing the structure of FIG. 3A, according to one embodiment.

FIGS. 4 through 6 are cross-sectional diagrams illustrating a structure for protecting a device, according to embodiments.

FIGS. 7A through 7C are microscope images of surfaces with hemispheric microstructures formed thereon.

FIG. 8 is a diagram illustrating distribution of stress in a hemispheric microstructure.

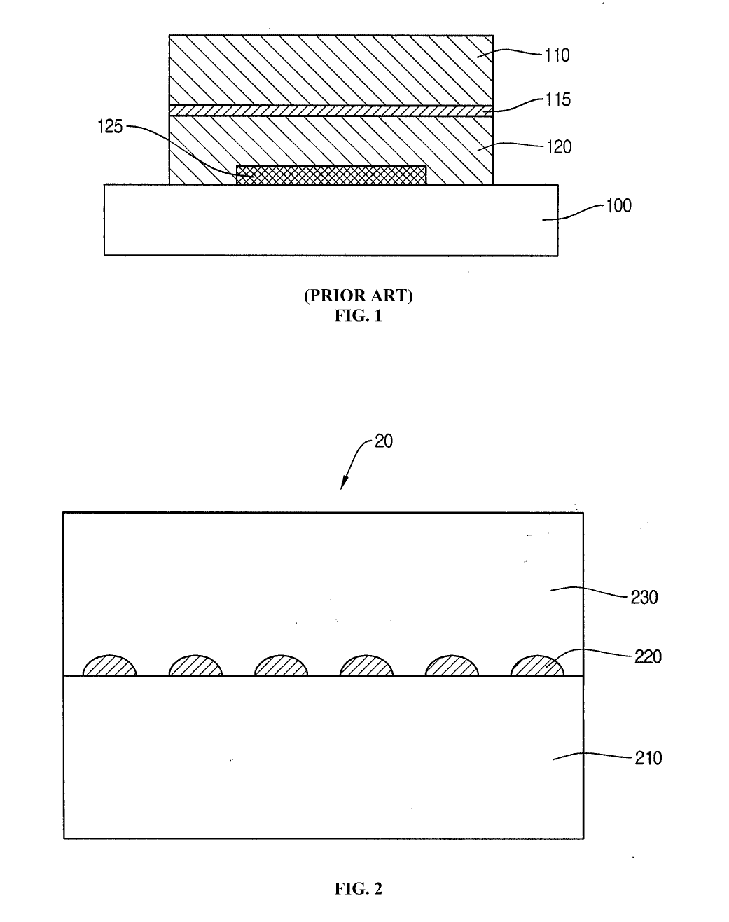

### DETAILED DESCRIPTION OF EMBODIMENTS

Embodiments are described herein with reference to the accompanying drawings. Principles disclosed herein may, however, be embodied in many different forms and should not be construed as being limited to the embodiments set forth herein. In the description, details of well-known features and techniques may be omitted to avoid unnecessarily obscuring the features of the embodiments.

In the drawings, like reference numerals in the drawings denote like elements. The shape, size and regions, and the like, of the drawing may be exaggerated for clarity.

FIG. 2 is a cross-sectional diagram illustrating a structure 20 for protecting a device according to an embodiment. The structure 20 may, among other components, comprise a first layer 210, at least one microstructure 220 and a second layer 230. In one embodiment, the first layer 210 comprises an inorganic material. The first layer 210 is provided on a device to be protected by the structure 20. The first layer 210 prevents ambient species from infiltrating into the device and affecting the device. Also, the first layer 210 and the device may be disposed on a substrate made of a flexible material.

One or more microstructures 220 are formed on the first layer 210. Each of the microstructure 220 may comprise a curved surface. For example, each microstructure 220 may have a shape of a hemisphere having a hemispheric surface. The microstructure 220 having a shape of a hemisphere may have a radius of, for example, 10 Å to 100 Å. 100 Å radius is sufficiently smaller than the thickness of a second layer (deposited on the microstructures 220 and the first layer 210) so that the microstructures 220 do not disrupt the shape of the upper surface of the second layer (i.e., the roughness of the upper surface of the second layer is not increased significantly). On the other hand, the microstructure 220 having a radius less that 10 Å is difficult to achieve using fabrication processes such as atomic layer deposition (ALD) processes.

One or more microstructures 220 may have a curved surface other than the hemispheric shape, and microstructures 220 may have shapes different from each other (e.g., irregular shape). Alternatively, each microstructure 220 may be in the form of a protruding or recessed structure. The microstructure 220 may be the same material as the first layer 210 or different from the first layer 210.

In one embodiment, the microstructures 220 are formed of metal, metal oxide, metal nitride, organic material, inorganic material or inorganic-organic hybrid material. For example, the microstructures 220 may comprise a ductile metal such as Al, Ag, Ni, Cu, In, Ga, etc. or oxide/nitride thereof. The microstructures 220 may be formed by the process of ALD, plasma treatment method or heat treatment processes. The microstructure 220 may comprise optically transparent material (e.g., Al₂O₃, In₂O₃, ZnO) to prevent obstruction of light passing through the substrates. Such microstructure 220 may be used advantageously, for example, in components of display devices (e.g., OLED device) or other optical devices.

The second layer 230 may be disposed on the first layer 210 and the microstructures 220. The second layer 230 may be disposed on a surface of the first layer 210 on which the microstructures 220 are disposed. In one embodiment, the second layer 230 is made of an inorganic material. The material of the second layer 230 may be the same as or different from that of the first layer 210.

In one embodiment, the first layer 210 and/or the second layer 230 are made of a material selected from a group consisting of Al₂O₃, AlN, NiO, ZnO, SiO₂ and SiN or a combination of two or more of them. Also, the first layer 210 and/or the second layer 230 may be formed by an ALD process. When compared with a layer formed by a chemical vapor deposition (CVD) process, a physical vapor deposition (PVD) process or a spray process, the first layer 210 and/or the second layer 230 formed by the ALD process has superior interfacial properties and film qualities and thus can effectively prevent the ingress of ambient species.

The structure 20 may experience stress during or after manufacturing thereof. Since the structure 20 has the microstructures 220 between the first layer 210 and the second layer 230, the area of the interface surface between the first layer 210 and the second layer 230 is increased. Since stress in structure 20 is dispersed throughout the increased area of the interface surface, the stress per a unit surface area is reduced. Accordingly, cracking of the structure 20 may be prevented or reduced. Further, since the microstructures 220 disposed at the interface surface increase the length of the infiltration path of ambient species, the infiltration of the ambient species can be decreased or prevented.

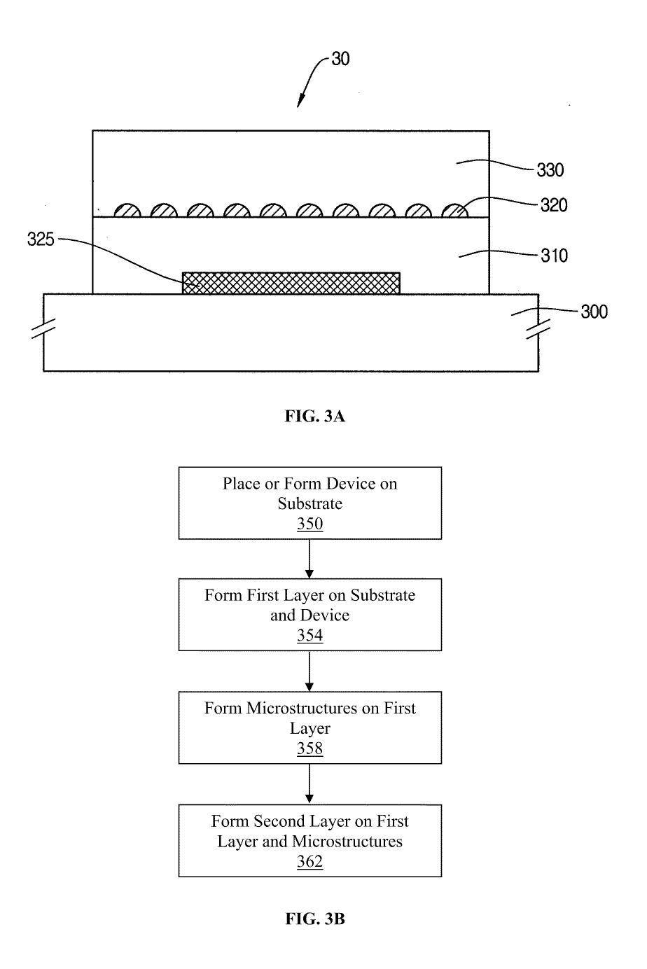

FIG. 3A is a cross-sectional diagram illustrating a structure 30 for protecting a device according to another embodiment. The structure 30 may comprise, among other components, a substrate 300, a device 325, a first layer 310, one or more microstructures 320 and a second layer 330. The first layer 310, the microstructures 320 and the second layer 330 have the same configurations as corresponding elements in the structure 20 of FIG. 2, and hence, detailed description of these components are omitted herein for the sake of brevity.

The substrate 300 may be made of a flexible material. For example, the substrate 300 comprises a polymer or plastic having a low melting point, a metal plate, graphite plate or glass plate processed to a thickness of about 0.2 mm or smaller, pulp paper, woven fabric, or the like. The device 325 may be disposed on the substrate 300. The device 325 is an element to be protected by the structure 30, and may, for example, be an active component of an electronic device.

When moisture, oxygen or other ambient species come into contact with the device 325, operating characteristics, shelf life, or the like of the device 325 may be negatively affected. In order to prevent this problem, the first layer 310 and the second layer 330 may be formed on the device 325 to shield the device 325 from the ambient species. The microstructures 320 may be disposed between the first layer 310 and the second layer 330. The microstructures 320 increase the area of the interface surface between the first layer 310 and the second layer 330. As a result, cracking of the first layer 310 and/or the second layer 330 due to stress may be prevented or reduced. Furthermore, since the length of the infiltration path of ambient species is increased, the ambient species can be prevented from coming into contact with the device 325.

FIG. 3B is a flowchart illustrating a method of manufacturing the structure 30, according to one embodiment. First, the device 325 is placed or formed 350 on the substrate 300. Then, the first layer 310 is formed 354 on a surface of the substrate 300 that includes the device 325. In one embodiment, the first layer 310 is made of an inorganic material. For example, the first layer 310 is an Al₂O₃ film having a thickness of 50 Å to 500 Å.

The Al₂O₃ film may be formed by an ALD process. In one example ALD process, the structure 30 is formed at a temperature of 100° C. or lower using trimethylaluminium (TMA) as a source precursor. As a reactant precursor, O₃ or H₂O may be employed. Alternatively, O₂ plasma or O* radical may be employed as the reactant precursor. The O₂ plasma or O* radical may be generated, for example, using a remote plasma method. In another embodiment, dimethylaluminumhydride (DMAH) ((CH₃)₂AlH) may be used as the source precursor and H₂ plasma or H* radical may be used as the reactant precursor to form the first layer 310 in the form of an Al film.

The microstructures 320 may be formed 358 on the resulting first layer 310. The microstructures 320 may be formed of metal, metal oxide, metal nitride, organic material, inorganic material, or inorganic-organic hybrid material. Taking an example of using a metal layer as the microstructure 320, metal is initially deposited in the form of nuclei, then grown into islands. Then, the islands are formed into a continuous film through coalescence as the thickness of the deposited material increases. By controlling the thickness of the deposited material, the microstructures 320, initially separated from each other, may merge to form a continuous film. For example, a metal such as Al, Cu, Ni, Ga, In, Ag, etc. is deposited to a thickness of 10 Å to 50 Å to form the microstructures 320.

When forming the microstructures 320 from a metal having a relatively low melting point such as Ga, In, etc. or a metal having a tendency to agglomerate (e.g., Ag, Cu), the microstructures 320 having a curved surface may be formed without a heat treatment process. In addition, after depositing the metal, the microstructures 320 having a curved surface may be formed as oxide or nitride through oxidation or nitriding. Meanwhile, in another embodiment, after depositing a film, the deposited material may be heat treated or exposed to hydrogen plasma to form the at least one microstructure 320. The heat treatment or plasma treatment may be performed under a vacuum condition.

When the microstructure 320 comprises a metal deposited in the form of nuclei, it may have a hemisphere-like shape. On the other hand, the microstructure 320 formed by heat treatment or plasma treatment tends to have an irregular, random shape. However, since both the hemispheric shape and the random shape provide the microstructure 320 with a larger surface area as compared to a plate-shaped interface surface, the stress in the interface surface may be dispersed effectively. As set forth above, the shape of the microstructure is not limited to the hemispheric shape or other particular shape.

Next, the second layer 330 may be formed 362 on the first layer 310 and the microstructures 320. The second layer 330 may comprise a material which is the same as or different from that of the first layer 310. For example, the second layer 330 is made of an Al₂O₃ film. The second layer 330 is substantially the same as that of the first layer 310, and detailed description thereof is omitted herein for the sake of brevity.

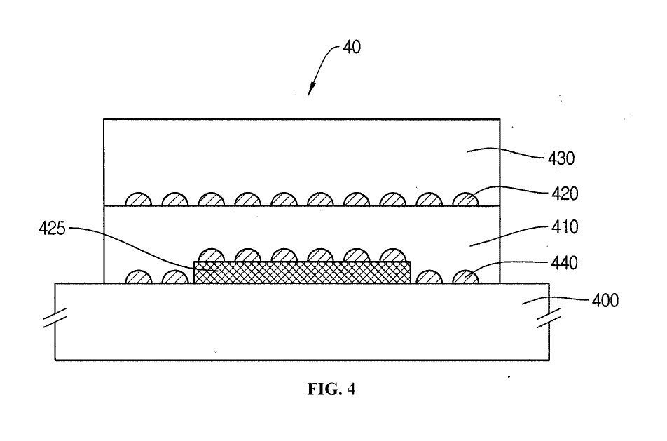

FIG. 4 is a diagram illustrating a structure 40 for protecting a device 425 according to another embodiment. The structure 40 may include, among other components, a substrate 400, a device 425, a first layer 410, one or more first microstructures 420, a second layer 430 and one or more second microstructures 440. The substrate 400, the device 425, the first layer 410 and the second layer 430 have the same configurations as corresponding elements in the structure 30 of FIG. 3A, and hence, detailed description thereof is omitted herein for the sake of brevity.

In addition to the first microstructures 420 disposed between the first layer 410 and the second layer 430, the structure 40 may further comprise the second microstructures 440 disposed on the substrate 400 and the device 425. The configuration of the second microstructures 440 may be the same as the configuration of the first microstructures 420. In one embodiment, each of the second microstructures 440 has a curved surface. For example, each second microstructure 440 has a hemispheric shape.

To manufacture the structure 40, the at least one second microstructure 440 is formed on the substrate 400 and the device 425 after the device 425 is disposed on the substrate 400. The method of forming the at least one second microstructure 440 is omitted herein since substantially the same method of forming the microstructures 325 of FIG. 3A may be used.

FIG. 5 is a cross-sectional diagram illustrating a structure 50 for protecting a device 525 according to another embodiment. The structure 50 may include, among other components, a substrate 500, a device 525, a first layer 510, first microstructures 520, a second layer 530, second microstructures 540 and a third layer 550. Detailed description about the substrate 500, the device 525, the first layer 510 and the second layer 530 is omitted here for the sake of brevity.

In addition to the first microstructures 520 disposed between the first layer 510 and the second layer 520, the structure 50 may further comprise the second microstructures 540 disposed on the bottom surface of the substrate 500. That is, the second microstructure 540 may be disposed on the surface of the substrate 500 opposite to the surface on which the device 525 is disposed. Accordingly, the at least one first microstructure 520 and the at least one second microstructure 540 are arranged to face opposite directions. For example, each of the first microstructure 520 may have a hemispheric shape protruding in one direction, and each of the second microstructure 540 may have a hemispheric shape protruding in a direction opposite to the one direction.

The third layer 550 may be formed on the bottom surface of the substrate 500 and the at least one second microstructure 540. In an embodiment, the third layer 550 may comprise an inorganic material. The third layer 550 may comprise a material which is the same as or different from that of the first layer 510 and the second layer 530.

When manufacturing the structure 50, the at least one second microstructure 540 may be formed first on the bottom surface of the substrate 500. Detailed description about the formation of the at least one second microstructure 540 will be omitted since it can be the same as the formation of the at least one microstructure described referring to FIG. 3A except that the deposition is performed on the opposite surface.

Next, the third layer 550 may be deposited on the bottom surface of the substrate 500 on which the at least one second microstructure 540 is formed. For example, the third layer 550 may be an Al₂O₃ layer having a thickness of 50 Å to 500 Å. The Al₂O₃ layer may be formed by a thermal ALD process using TMA as a source precursor and using O₃ or H₂O as a reactant precursor. Alternatively, the Al₂O₃ layer may be formed by plasma-assisted ALD or radical-assisted ALD using O₂ plasma or O* radical as a reactant precursor. The third layer 550 may be deposited at a temperature of 100° C. or lower.

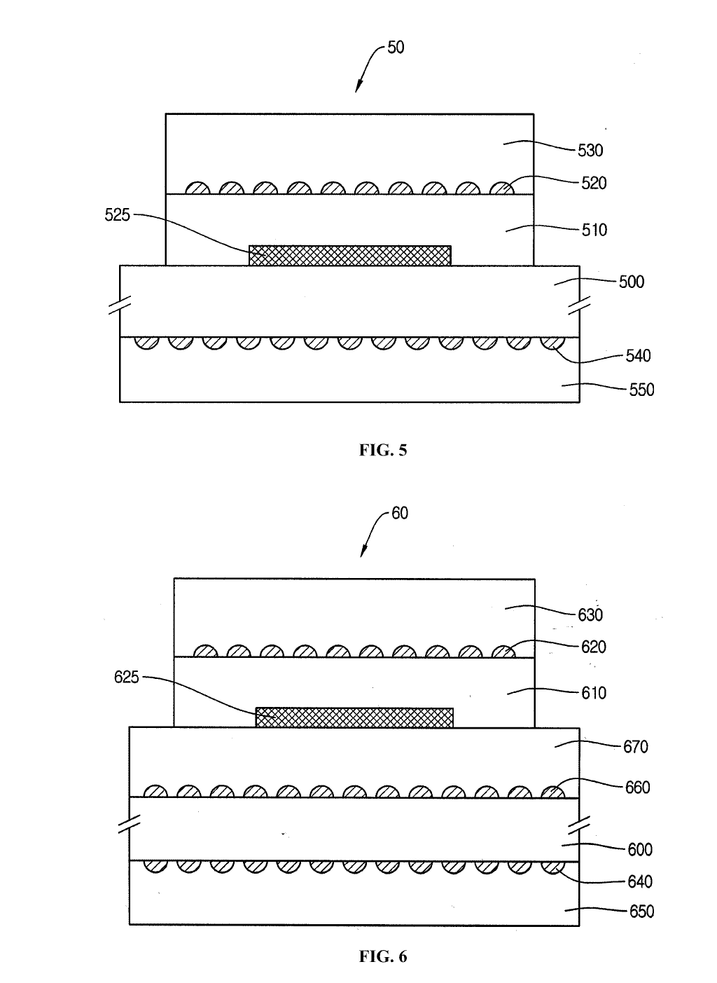

FIG. 6 is a cross-sectional diagram of a structure 60 for protecting a device 625 according to still another embodiment. The structure 60 may include, among other components, a substrate 600, a device 625, a first layer 610, first microstructures 620, a second layer 630, second microstructures 640, a third layer 650, at least one third microstructure 660 and a fourth layer 670. Detailed description about the substrate 600, the device 625, the first layer 610, the at least one first microstructure 620, the second layer 630, the at least one second microstructure 640 and the third layer 650 is omitted herein for the sake of brevity.

The structure 60 may further comprise the at least one third microstructure 660 and the fourth layer 670 disposed on the substrate 600. The at least one third microstructure 660 may be disposed on the surface of the substrate 600 opposite to the surface on which the at least one second microstructure 640 is formed. For example, each of the second microstructure 640 has a hemispheric shape protruding in one direction, and each of the third microstructure 660 has a hemispheric shape protruding in an opposite direction. The fourth layer 670 may be formed on the surface of the substrate 600 on which the at least one third microstructure 660 is formed. The device 625 may be disposed on the fourth layer 670.

To manufacture the structure 60, third microstructures 660 may be formed first on the substrate 600 before the device 625 is disposed on the substrate 600. Substantially the same method of forming microstructures as described with reference to FIG. 3A may be applied to the structure 60, and hence, detailed description about the method of forming is omitted herein. Next, the fourth layer 670 may be deposited on the substrate 600 on which the at least one third microstructure 660 is deposited. Since the at least one third microstructure 660 and the fourth layer 670 are formed prior to the disposition of the device 625, the device 625 is not affected by the process for the formation of the at least one third microstructure 660 and the fourth layer 670. Accordingly, the third microstructures 660 and the fourth layer 670 may be formed by processes such as an ALD process.

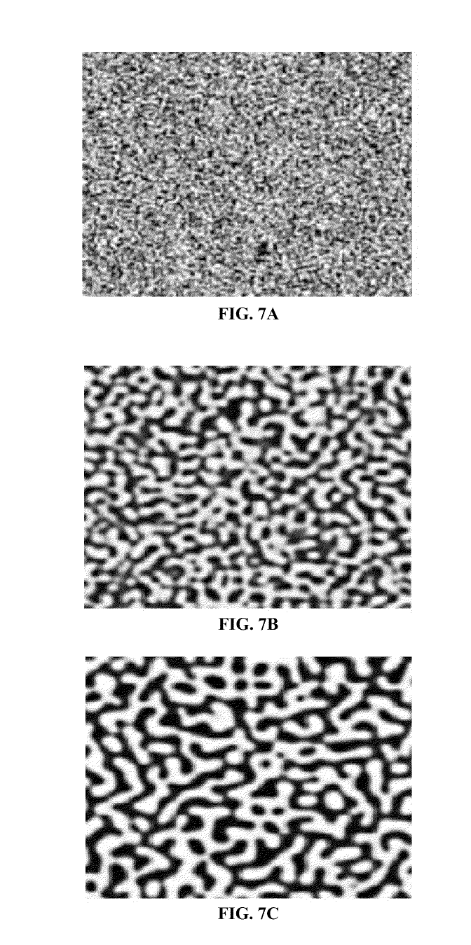

FIGS. 7A through 7C are microscope images of surfaces with hemispheric microstructures formed thereon. FIGS. 7A, 7B and 7C are microscope images of microstructures formed by depositing Ag to a thickness of 15 Å, 30 Å and 50 Å, respectively. As seen from FIGS. 7A through 7C, each microstructure may have a hemispheric shape or any other arbitrary shape. Further, the shapes of the microstructures may not be identical.

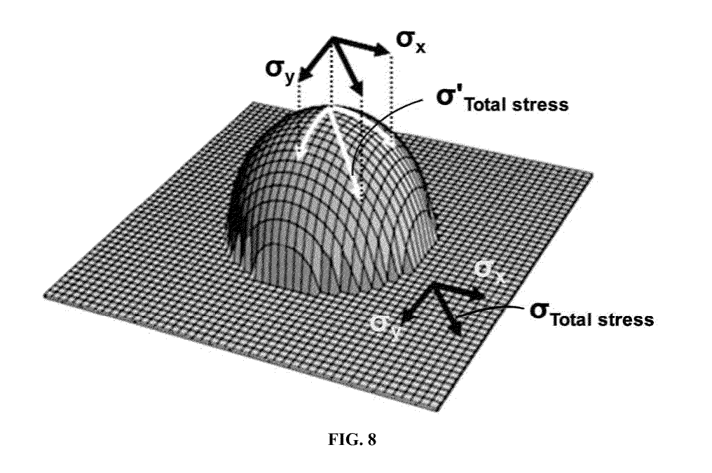

FIG. 8 is a diagram illustrating the distribution of stress in a hemispheric microstructure. Referring to FIG. 8, a microstructure may be presumed to have a hemispheric shape with a radius r. Then, the microstructure has a surface area of 2πr². Suppose that the microstructure does not exist, the plate-shaped surface has a surface area of πr², which corresponds to the bottom surface area of the microstructure. Accordingly, the formation of the microstructure having a hemispheric shape results in a surface area increased by a factor of two. Since the total stress σ applied to the plate-shaped surface and the total stress σ′ applied to the hemispheric microstructure are the same in magnitude, the stress applied per unit area is reduced to ½ as the surface area is increased 2-fold by the microstructure.

As described above, microstructures may be formed between the layers formed on the device to be protected. For example, microstructures are formed between inorganic layers, between an organic layer and an inorganic layer, between an inorganic-organic hybrid layer and an inorganic layer, or between an inorganic-organic hybrid layer and an organic layer. Each microstructure may have any shape capable of increasing the interface surface between the layers. For example, each microstructure has a hemispheric shape or other shape with a curved surface.

By increasing the area of the interface surface with the at least one microstructure, the stress applied per unit area of the interface surface may be reduced. Furthermore, by increasing the length of the path that ambient species need to travel in order to reach a device or other active components, the infiltration of ambient species may be prevented or decreased. In addition, by forming the layers which contact the at least one microstructure as a film having a covalent or ionic bonding using an ALD process, the infiltration of the ambient species through the layers may be prevented or decreased.

Although the present invention has been described above with respect to several embodiments, various modifications can be made within the scope of the present invention. Accordingly, the disclosure of the present invention is intended to be illustrative, but not limiting, of the scope of the invention, which is set forth in the following claims.

What is claimed is:

1. A structure enclosing a device, the structure comprising:
a first layer;
one or more first microstructures formed on the first layer, each of the first microstructures having a first curved surface protruding from the first layer; and
a second layer formed on the first layer and the one or more first microstructures, the second layer and the first microstructures of different materials.

2. The structure according to claim 1, wherein the first curved surface comprises a hemispheric surface.

3. The structure according to claim 1, wherein the first microstructure is made of one of metal, metal oxide, metal nitride, organic material, inorganic material or organic-inorganic hybrid material.

4. The structure according to claim 1, wherein the first microstructure has a thickness of 10 Å to 100 Å.

5. The structure according to claim 1, further comprising a flexible substrate on which the device is placed.

6. The structure according to claim 5, further comprising second microstructures formed on the flexible substrate and the device, each of the second microstructures having second curved surfaces protruding from the flexible substrate or the device.

7. The structure according to claim 6, wherein the second curved surface comprises a hemispheric surface.

8. The structure according to claim 7, wherein the second microstructures is made of one of metal, metal oxide, metal nitride, organic material, inorganic material and organic-inorganic hybrid material.

9. The structure according to claim 8, wherein the second microstructures have a thickness of 10 Å to 100 Å.

10. The structure according to claim 1, wherein the first microstructures are made of optically transparent material.

11. A method for manufacturing a structure enclosing a device, the method comprising:
forming a first layer on the device;
forming one or more microstructures on the first layer, each of the microstructures having a curved surface protruding from the first layer; and
forming a second layer on the first layer and the one or more microstructures, the second layer and the one or more microstructures of different materials.

12. The method according to claim 11, wherein the one or more microstructures are formed using an atomic layer deposition (ALD) process.

13. The method according to claim 12, wherein the first layer or the second layer is made of an inorganic material having a thickness of 50 Å to 500 Å.

14. The method according to claim 13, wherein the inorganic material is selected from a group consisting of Al₂O₃, AN, NiO, ZnO, SiO₂, SiN and a combination thereof.

15. The method according to claim 14, wherein the one or more microstructures comprise a metal, metal oxide, metal nitride, organic material, inorganic material or organic-inorganic hybrid material.

16. The method according to claim 15, wherein the metal is selected from a group consisting of Al, Cu, Ni, Ga, In, Ag and a combination thereof.

17. The method according to claim 11, wherein one or more microstructures have a thickness of 10 Å to 100 Å.

18. The method according to claim 11, wherein forming the one or more microstructures comprises oxidizing metal deposited on the first layer.

19. The method according to claim 11, wherein forming the one or more microstructures comprises nitrating metal deposited on the first layer.

20. The method according to claim 11, wherein forming the one or more microstructures comprises:
depositing a film on the first layer; and
exposing the film to heat or plasma.
